(19) United States
(12) Patent Application Publication
(10) Pub. No.: US 2011/0161786 A1
(43) Pub. Date: Jun. 30, 2011

(54) METHOD FOR COPING WITH PACKET ERROR DISTRIBUTION, A SERVER APPARATUS, AND A TERMINAL APPARATUS

(76) Inventor: Satoshi Nishiyama, Hino-shi (JP)

(21) Appl. No.: 12/968,119

(22) Filed: Dec. 14, 2010

(30) Foreign Application Priority Data
Dec. 25, 2009 (JP) 2009-296324

(51) Int. Cl. H03M 13/05; G06F 11/10

(52) U.S. Cl. 714/776; 714/E11.032

(57) ABSTRACT

According to one embodiment, a server apparatus includes a judgment module and a controller. The judgment module judges a communication connection state of the terminal that made the notification, when a message indicating that error reception of an unnecessary packet is detected by the terminal. The controller executes a process of preventing packet error distribution according to the communication connection state judged by the judgment module.

### CROSS-REFERENCE TO RELATED APPLICATIONS

This application is based upon and claims the benefit of priority from Japanese Patent Application No. 2009-296324, filed Dec. 25, 2009; the entire contents of which are incorporated herein by reference.

### FIELD

Embodiments described herein relate generally to a communication system that provides audio communications between terminals via an IP network, such as an Internet Protocol (IP) telephone system, and more particularly, to a method for coping with a packet error distribution in order to prevent distribution of unnecessary packets to terminals, in particular, and a server apparatus and a terminal apparatus used in this communication system.

### BACKGROUND

In recent years, IP telephone systems that transmit and receive images and audios in real time as packet data bi-directionally via IP networks have become popular. In such an IP telephone system, exchange servers and a plurality of IP terminals are connected to an IP network, and communications can be performed between the IP terminals or between an IP terminal and a trunk in each of the exchange servers.

In the above-described IP telephone system, since occurrence of packet error distribution cannot be automatically detected by the exchange server, occurrence of the problem is recognized based on report of the user, and maintenance person collects and analyzes the packet of the section that is suspicious of the cause for the occurrence of the problem. For example, when a Real-time Transport Protocol (RTP) packet is distributed by error for some reason, the user reports that an unnecessary audio is heard, the audio is heard only on one side, the audio is not heard at all, or the like. Based on such a report, the problem is recognized, and analysis for cause investigation is performed manually.

As a related technique, an approach has been proposed in which a subscriber terminal device configured to prevent denial-of-service/distributed denial-of-service attacks (DoS/DDoS attacks) detects a DoS/DDoS attack, re-acquires an IP address from a collective-side device of a host communication device when the load of the CPU has exceeded a certain threshold value, and changes its IP address (see Jpn. Pat. Appln. KOKAI Publication No. 2006-254269).

The above-described technique is compliant only with the packet attack from an external network, and does not take measures against the packet error distribution, other than packet attacks.

Further, occurrence of packet error distribution causes the following phenomenon:

(1) Since the packet error distribution involves unnecessary procedures, the load on the processing capability is increased both on the transmission and reception sides. When a CPU with a low processing capability is used in a device in the system, the distribution side or the reception side will not be able to provide its functions.

(2) Unintended data may leak if the reception side receives a packet distributed by error. In the case of audio communications, for example, unintended conversation of other people may be heard. This is not preferable in terms of security.

(3) Unnecessary packets flow to the IP network and load the bandwidth. When the bandwidth of the IP network is narrow, delay occurs in packet transmission/reception. In the worst case, congestion occurs, and the system needs to be stopped to cope with that.

Due to the above-described phenomena that cannot be solved instantly, the system cannot be normally operated, and the user suffers disadvantages of a slowdown in work of the user, which causes an adverse effect to performance, and a redundant cost until the problem is solved. Further, since the maintenance person in charge cannot perform other operations while analyzing the problem of packet error distribution, the maintenance operation may be interfered, or redundant maintenance expenses may be required.

### BRIEF DESCRIPTION OF THE DRAWINGS

A general architecture that implements the various feature of the embodiments will now be described with reference to the drawings. The drawings and the associated descriptions are provided to illustrate the embodiments and not to limit the scope of the invention.

FIG. 1 is a schematic configuration diagram illustrating an IP telephone system according to a first embodiment;

FIG. 2 is a block diagram illustrating a configuration of an exchange server shown in FIG. 1;

FIG. 3 illustrates an example of a content stored in an IP terminal call state data table shown in FIG. 2;

FIG. 4 illustrates an example of a content stored in an IP terminal setting table shown in FIG. 2;

FIG. 5 is a block diagram illustrating a configuration of an IP telephone terminal according to the first embodiment;

FIG. 6 is a flowchart illustrating a control processing procedure of an IP telephone terminal that performs error detection of an unnecessary packet according to the first embodiment;

FIG. 7 is a flowchart illustrating the control processing procedure of an exchange server compliant with error detection of unnecessary packets, according to the first embodiment;

FIG. 8 is a block diagram illustrating a configuration of an exchange server according to a second embodiment;

FIG. 9 is a flowchart illustrating a control processing procedure of an exchange server compliant with error detection of an unnecessary packet according to the second embodiment;

FIG. 10 is a flowchart illustrating a control processing procedure in which a recovery process “0” of packet error distribution is executed, according to the second embodiment;

FIG. 11 is a flowchart illustrating a control processing procedure in which a recovery process “1” of packet error distribution is executed, according to the second embodiment; and

FIG. 12 is a flowchart illustrating the control processing procedure in which a recovery process “2” of packet error distribution is executed according to the second embodiment.

### DETAILED DESCRIPTION

Various embodiments will be described hereinafter with reference to the accompanying drawings. In general, according to one embodiment, a server apparatus executing communication connection between a plurality of terminals connected to a communication network for packet communications, comprising: a judgment module configured to judge a communication connection state of the terminal that made the notification, when a message indicating that error reception of an unnecessary packet is detected by the terminal; and a controller configured to execute a process of preventing packet error distribution according to the communication connection state judged by the judgment module.

### First Embodiment

The first embodiment is configured such that an alarm notification process is executed according to a call connection state of an IP telephone terminal that has made the notification in response to error reception of a packet.

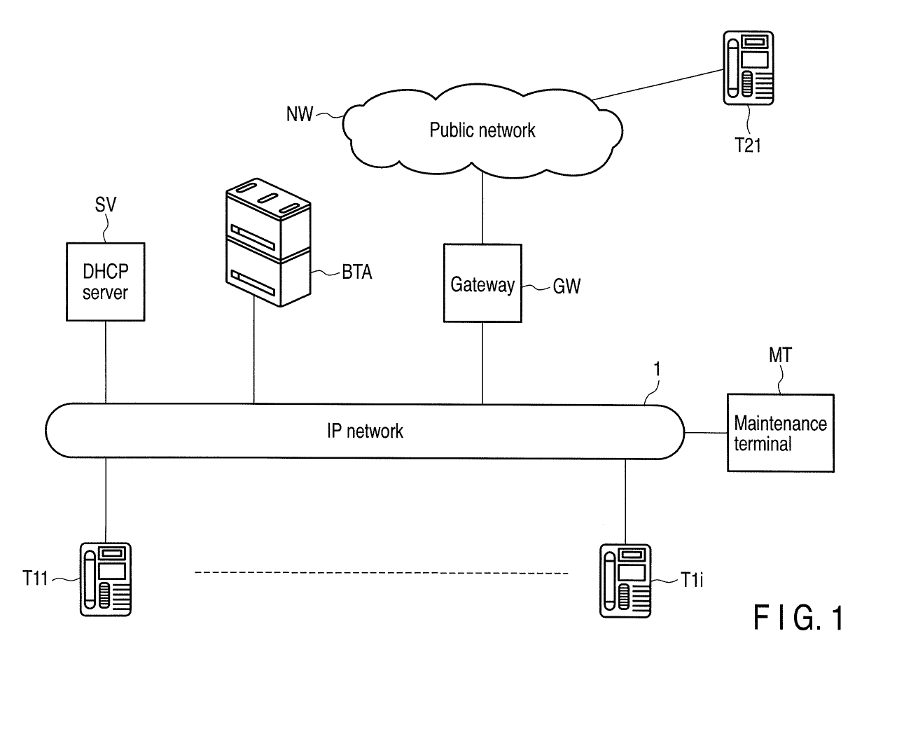

FIG. 1 is a schematic configuration diagram illustrating an IP telephone system according to a first embodiment.

This system includes a local area network (LAN) as a communication network for packet communications and an IP network 1 including the Internet, for example. A plurality of IP telephone terminals T11-T1i are connected to the IP network 1 (where i is a natural number). The IP telephone terminals T11-T1i are provided with a communication processing function and a media information processing function. Further, the IP network 1 includes a plurality of media channels and a control channel via which a control signal necessary for determining the media channel is transferred.

Further, a gateway GW is connected to the IP network 1. The gateway GW is designed to connect the IP network 1 and a public network NW, such as an analogue telephone network, and is equipped with an exchange function of the communication protocol and the signal format between the IP network 1 and the public network NW. A telephone terminal T21, such as a standard telephone apparatus, is connected to the public network NW.

Further, an exchange server BTA as a server apparatus, a Dynamic Host Configuration Protocol (DHCP) server SV, and a maintenance terminal MT are connected to the IP network 1. The exchange server BTA is equipped with an exchange control function with respect to the IP telephone terminals T11-T1i and the gateway GW, an IP address allocation function with respect to the IP telephone terminals T11-T1i and the gateway GW, and an address management function of managing addresses allocated to the IP telephone terminals T11-T1i and the gateway GW.

The IP address allocation function is configured such that a vacant IP address is allocated from among the IP addresses held by the DHCP server SV when each of the IP telephone terminals T11-T1i and the gateways GW is activated.

The address management function is configured such that a telephone number as a terminal ID allocated in advance to each of the IP telephone terminals T11-T1i and the gateway, a Media Access Control (MAC) address as a fixed network address, and the IP address allocated to each of the IP telephone terminals T11-T1i and the gateway GW is managed.

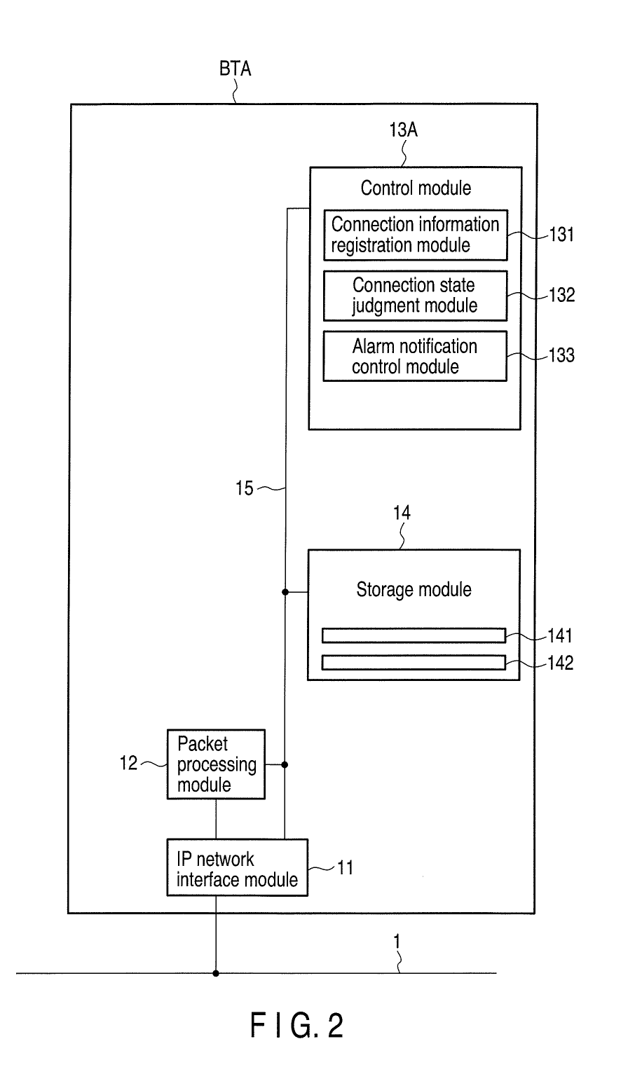

The exchange server BTA is equipped with functions as will be described below, as functions relating to the embodiment. FIG. 2 is a block diagram illustrating its configuration.

That is, the exchange server BTA includes an IP network interface module 11, a packet processing module 12, a control module 13A, and a storage module 14. The IP network interface module 11, the packet processing module 12, the control module 13A, and the storage module 14 are connected to one another via a data highway 15.

The IP network 1 is connected to the IP network interface module 11, as necessary. The IP network interface module 11 performs an interface process with the connected IP network. Further, the IP network interface module 11 performs transmission and reception of a variety of control information relating to the interface processing to and from the control module 13A via the data highway 15.

The packet processing module 12 processes a control packet and a RTP packet (or an audio packet) received from the IP network 1.

The control module 13A includes a CPU, a ROM, and a RAM, and controls each module of the exchange server BTA through a software process.

The storage module 14 stores routing information, for example, necessary for connection control of the control module 13A. Further, the storage module 14 is provided with an IP terminal call state data table 141 (hereinafter simply referred to as a data table 141) and an IP terminal setting table 142 (hereinafter simply referred to as a setting table 142).

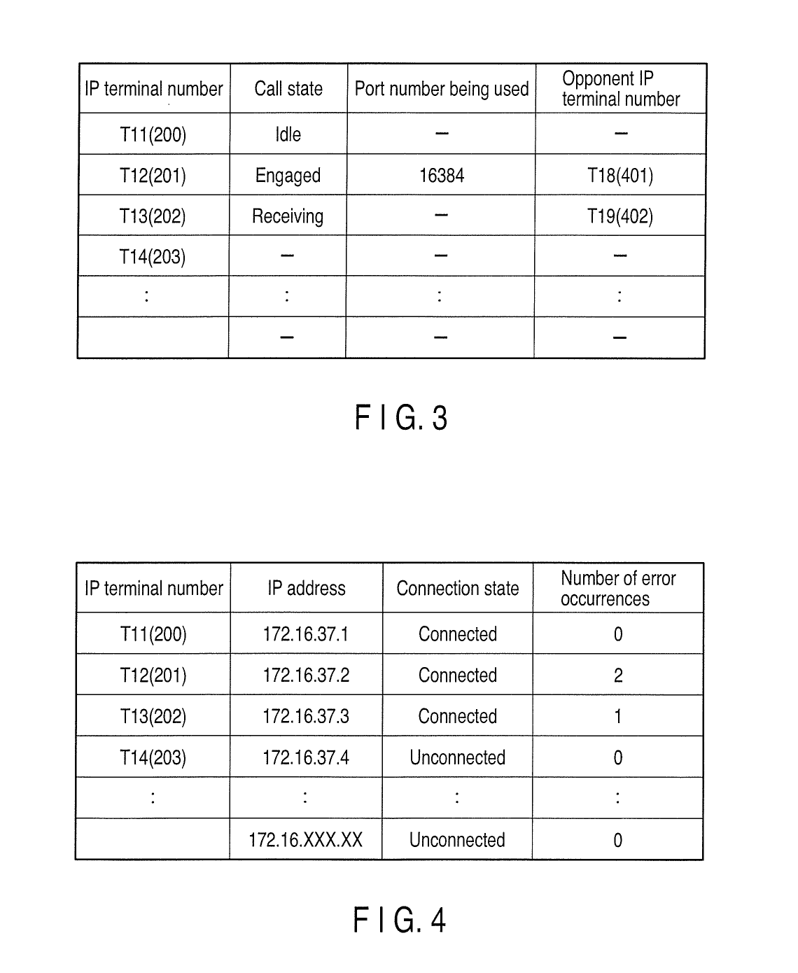

The data table 141 stores data indicating the correspondence relationship between the IP terminal number (telephone number), the call state, the port number being used, the IP terminal number (telephone number) on the other end of each of the IP telephone terminals T11-T1i and the gateway GW, as shown in FIG. 3.

The setting table 142 stores data indicating the correspondence relationship between the IP terminal number (telephone number), the IP address, the connection state, and the number of occurrence of errors of each of the IP telephone terminals T11-T1i and the gateways GW, as shown in FIG. 4.

In addition to the exchange control function and the address management function of the IP telephone terminals T11-T1i and the gateways GW, the control module 13A includes a connection information registration module 131, a connection state judgment module 132, and an alarm notification control module 133 as new functions relating to the embodiment.

The connection information registration module 131 judges that the IP telephone terminal T12 and the IP telephone terminal T18 have engaged in a call, and additionally updates information on the IP telephone terminal T12 in the data table 141 and the setting table 142.

When the connection state judgment module 132 is notified of a message indicating detection of error reception of an unnecessary packet from the IP telephone terminal T11, the connection state judgment module 132 refers to the data table 141 and the setting table 142 based on the IP terminal number included in the message, and judges the communication connection state of the IP telephone terminal T11 that has made the notification, based on the reference result.

The alarm notification control module 133 notifies the IP telephone terminal T11 that has made the notification and the maintenance terminal MT on the IP network 1 of an alarm message according to the communication connection state judged by the connection state judgment module 132.

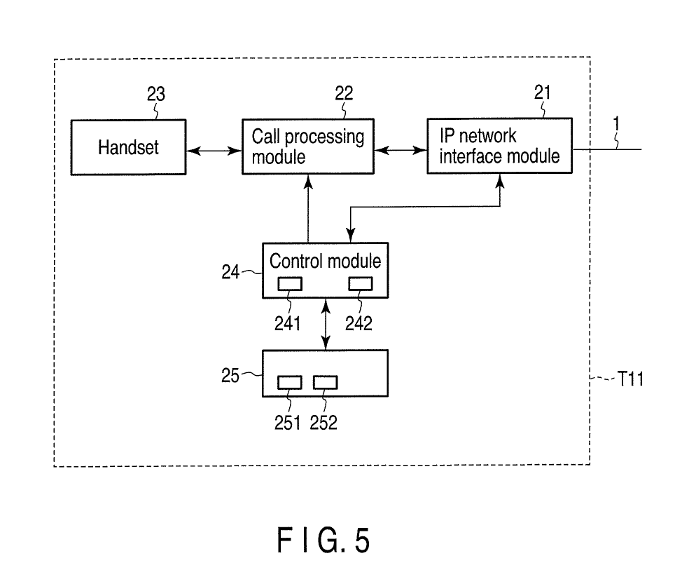

FIG. 5 is a block diagram illustrating the configuration of the IP telephone terminals T11-T1i. Here, a description will be made with reference to the IP terminal T11 as a representative.

In FIG. 5, the IP telephone terminal T11 includes an IP network interface module 21, a call processing module 22, a handset 23, a control module 24, and an operation panel module 25.

The IP network interface module 21 performs transmission and reception of data of various kinds via the IP network 1. Further, the IP network interface module 21 extracts a call signal and a control signal from the RTP packet transmitted from the IP network 1, and supplies the call signal to the call processing module 22 and the control signal to the control module 24. Further, the IP network interface module 21 generates a transfer signal by multiplexing a serial data signal supplied from the call processing module 22 and the control module 24 by time division and transmits the transfer signal to the IP network 1 as an RTP packet.

The call processing module 22 retrieves communication data included in the communication signal supplied from the IP network interface module 21, and plays back an analogue reception audio signal from the communication data. Further, the communication processing module 22 drives a receiver of a handset 23 based on the played-back reception audio signal, and causes the receiver to output a reception audio. Further, an analogue transmission audio signal generated in a transmitter of the handset 23 is input to the call processing module 22. The call processing module 22 converts the transmission audio signal into a communication signal of a predetermined form, and supplies it to the IP network interface module 21.

The control module 24 includes a CPU, a ROM, and a RAM, and controls each module of the IP telephone terminal T11 through a software process.

The operation panel module 25 includes a display module 251, such as a liquid crystal display (LCD), and a key input module 252. On the display module 251, a variety of information indicating the operation state of the device itself output from the control module 24, such as a telephone directory, is also displayed.

The control module 24 includes a packet error reception detection module 241 (hereinafter simply referred to as detection module 241), and a packet error reception notification module 242 (hereinafter simply referred to as notification module 242). The detection module 241 detects error reception of an unexpected, unnecessary packet from an unused port.

The communication module 242 notifies the exchange server BT of a message indicating detection of error reception upon detection of error reception of an unnecessary packet from the detection module 241.

Next, the operation will be described with the above-described configuration.

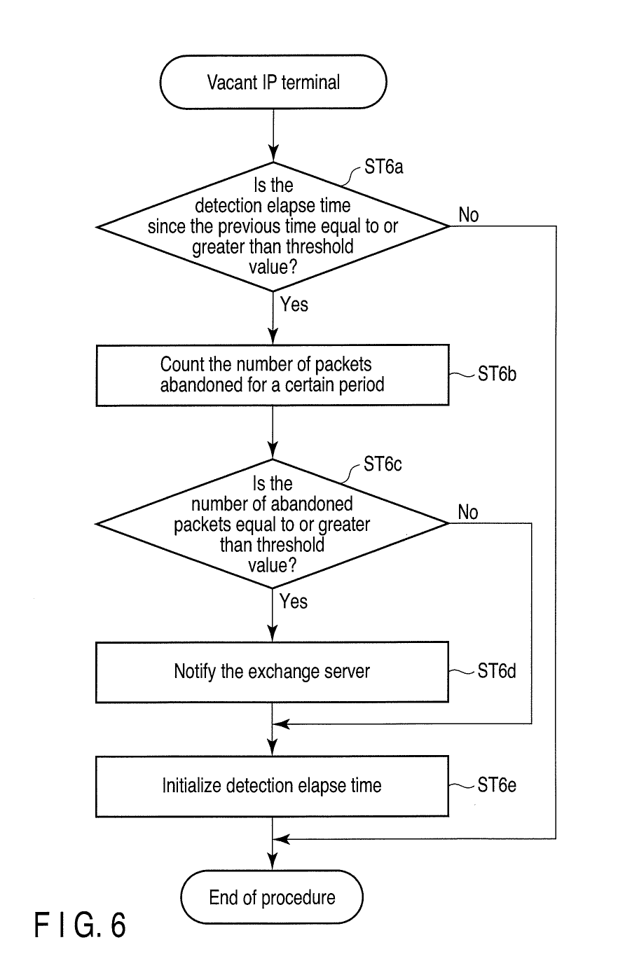

FIG. 6 is a flowchart illustrating the control processing procedure of the IP telephone terminals T11-T1i, in which error detection of unnecessary packets is performed.

(Outgoing Operation from the IP Telephone Terminal T12 to the IP Telephone Terminal T18)

Assume that the user has performed a dial operation “401” in the IP telephone terminal T12, in order to start a call with the user of the IP telephone terminal T18. The IP telephone terminal T12 then transmits a communication establishment request signal to the exchange server BTA. Upon receipt of the communication establishment request signal, the exchange server BTA calls the IP telephone terminal T18 to which a call is made. The IP telephone terminal T18 responds thereto, and establishes a communication link between the IP telephone terminal T12 and the IP telephone terminal T18.

Thereby, the user of the IP telephone terminal T12 can start a call with the user of the IP telephone terminal T18.

Further, the exchange server BTA stores the IP terminal number of the IP telephone terminal T12, the call state “engaged in a call”, the port number “16384” used to specify the communication link, and the IP terminal number of the IP telephone terminal T18 on the other end in the IP terminal call state data table 141, by associating them with one another.

When the call between the IP telephone terminal T12 and the IP telephone terminal T18 ends, the exchange server BT updates the call state of the IP telephone terminal T12 of the IP terminal call state data table 141 from “engaged in a call” to “idle”, and deletes the port number.

The IP telephone terminal T12 calculates the preset period of time from the point in time when the call has ended, and judges whether a packet exists that has been abandoned during that period, or whether a period of time greater than a threshold value has elapsed from the previous detection of unnecessary packet reception (block ST6a). When an abandoned packet does not exist, the set period of time has elapsed, or the period of time that has elapsed after the previous detection of unnecessary packet reception is smaller than the threshold value (NO), the IP telephone terminal T12 ends the procedure.

When the packet has been abandoned during the set period of time, or the period of time that has elapsed after the previous detection of unnecessary packet reception is equal to or greater than a threshold value (YES), the IP telephone terminal T12 counts the number of abandoned packets (block ST6b), and judges whether the number of abandoned packets is equal to or greater than a threshold value (block ST6c).

In this case, when the number of abandoned packets is equal to or greater than a threshold value (YES), the IP telephone terminal T12 notifies the exchange server BT of a message indicating that unnecessary packet reception has been detected (block ST6d), initializes the detection elapse time (block ST6e), and ends the procedure.

When the number of abandoned packets is less than a threshold value (NO), the IP telephone terminal T12 shifts to block ST6e.

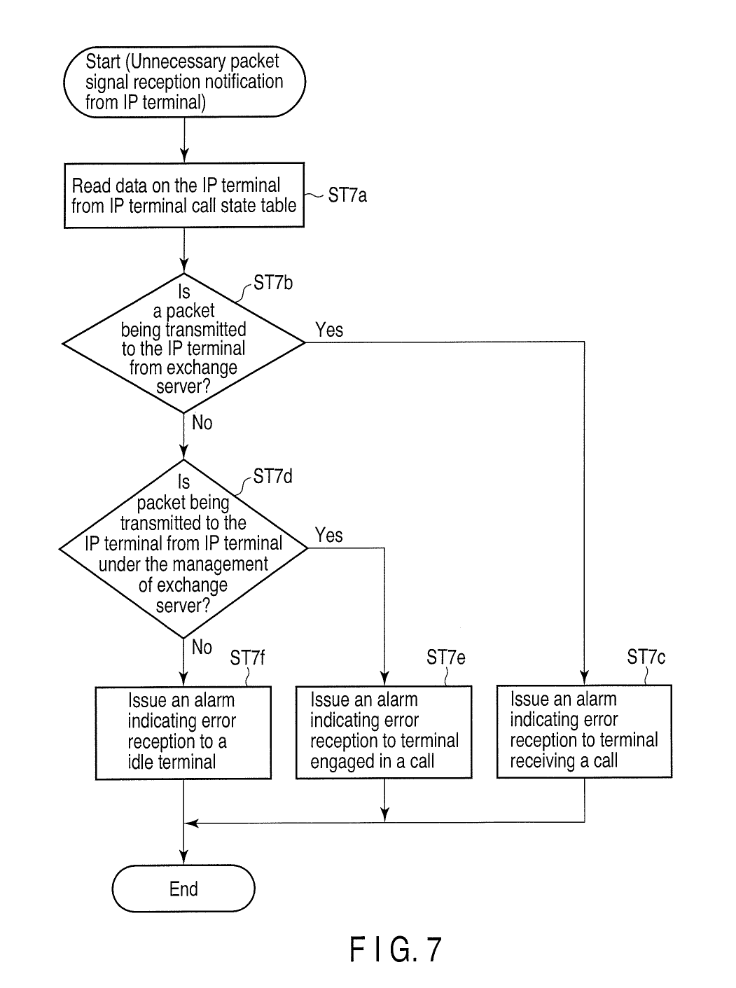

FIG. 7 is a flowchart illustrating the control processing procedure of the exchange server BTA.

When the exchange server BTA has received a message notifying the exchange server BTA of unnecessary packet reception from the IP telephone terminal T12, the exchange server BTA reads data on the IP telephone terminal T12 from the IP terminal call state table 141 (block ST7a).

Next, the exchange server BTA judges whether a packet is being transmitted from the exchange server BT to the IP telephone terminal T12, using the read value (block ST7b). When a packet is being transmitted to the IP telephone terminal T12 (YES), the exchange server BTA notifies the IP telephone terminal T12 or the maintenance terminal MT of an alarm indicating the error reception to the “terminal receiving a call” (block ST7c).

On the other hand, when a packet is not being transmitted from the exchange server BTA to the IP telephone terminal T12 (NO), the exchange server BTA judges whether a packet is being transmitted to the IP telephone terminal T12 from the IP telephone terminal T18 under the management of the exchange server BTA, using the read value (block ST7d).

When a packet is being transmitted from the IP telephone terminal T18 under the management of the exchange server BTA to the IP telephone terminal T12 (YES), the exchange server BTA notifies the IP telephone terminal T12 or the maintenance terminal MT of an alarm indicating the error reception to the “terminal engaged in a call” (block ST7e).

When a packet is not being transmitted from the IP telephone terminal T18 under the management of the exchange server BTA to the IP telephone terminal T12 (NO), the exchange server BTA informs the IP telephone terminal T12 or the maintenance terminal MT of an alarm indicating the error reception to the “idle terminal” (block ST7f).

As described above, according to the first embodiment, each of the IP telephone terminals T11-T1i includes a detection module 241 configured to automatically detect error reception of packets, and at the point in time when the packet error reception has been detected by the IP telephone terminals T11-T1i, the detected result is notified to the exchange server BTA. Upon receipt of the notification, the exchange server BTA refers to the table 141, judges the call connection state of each of the IP telephone terminals T11-T1i that has made the notification, and informs the IP telephone terminal that has made the notification or the maintenance terminal MT of an alarm message according to the call connection state. Further, guidance information on the recovery operation of the packet error reception may also be included in the alarm message.

Accordingly, the user of the IP telephone terminal T11 that has made the notification or the user of the maintenance terminal MT, for example, instantly knows that the packet error distribution has occurred in the IP telephone terminal T11, and thereby measures can be taken promptly by performing a recovery operation, for example, according to the call connection state of the corresponding IP telephone terminal T11. Thus, recovery can be made at a short period of time and at a low cast.

Further, according to the first embodiment, the number of abandoned packets is counted in the preset period of time, and when the number is equal to or greater than a threshold value, it is judged that packet error reception has occurred. Accordingly, the reliability in judgment of the packet error reception can further be improved while suppressing the IP telephone terminals T11-T1i at a low cast, by not judging that the packet error reception has occurred when the abandoned packet is temporary, and judging that packet error reception has occurred when abandoned packets continue.

### Second Embodiment

The second embodiment is configured such that a recovery process is executed according to the call connection state of the IP telephone terminal that has made the notification in response to packet error reception.

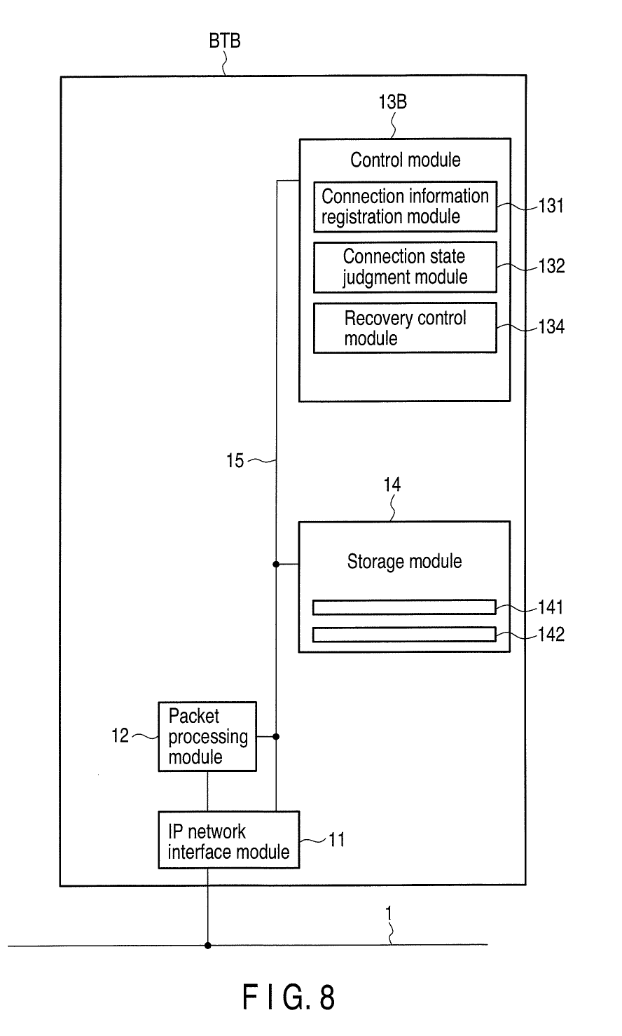

FIG. 8 is a block diagram illustrating the configuration of the exchange server BTB according to the second embodiment. In FIG. 8, structural elements same as those of FIG. 2 will be referred to by the same reference numerals, and detailed description of such elements will be omitted.

A recovery control module 134 is provided in the control module 13B of the exchange server BTB. The recovery control module 134 activates a recovery process according to the communication connection state judged by the connection state judgment module 132 in the IP telephone terminal T11 that has made the notification, for example, and notifies the maintenance terminal MT on the IP network of error information.

Next, the operation will be described with the above-described configuration.

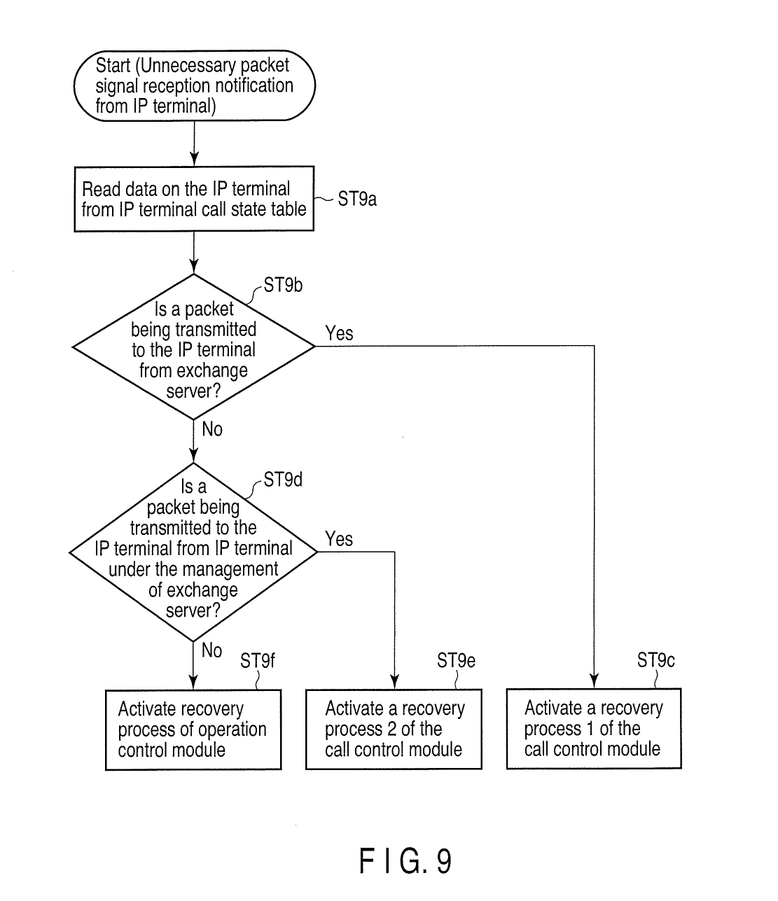

FIG. 9 is a flowchart illustrating the control processing procedure of the exchange server BTB.

When the exchange server BTB receives a message notifying reception of an unnecessary packet from the IP telephone terminal T12, data on the IP telephone terminal T12 is read from the IP terminal call state table 141 (block ST9a).

Next, the exchange server BTB judges whether a packet is being transmitted to the IP telephone terminal T12 from the exchange server BT, using the read value (block ST9b). In this case, when a packet is being transmitted to the IP telephone terminal T12 (YES), the exchange server BT activates a recovery process “1” (block ST9c).

When a packet is not being transmitted to the IP telephone terminal T12 from the exchange server BTB (NO), the exchange server BT uses the read value, and judges whether a packet is being transmitted to the IP telephone terminal T12 from the IP telephone terminal T18 under the management of the exchange server BT (block ST9d).

When a packet is being transmitted from the IP telephone terminal T18 under the management of the exchange server BTB to the IP telephone terminal T12 (YES), the exchange server BT activates a recovery process “2” (block ST9e).

When a packet is not being transmitted to the IP telephone terminal T12 from the IP telephone terminal T18 under the management of the exchange server BTB (NO), the exchange server BT activates a recovery process “0” (block ST9f).

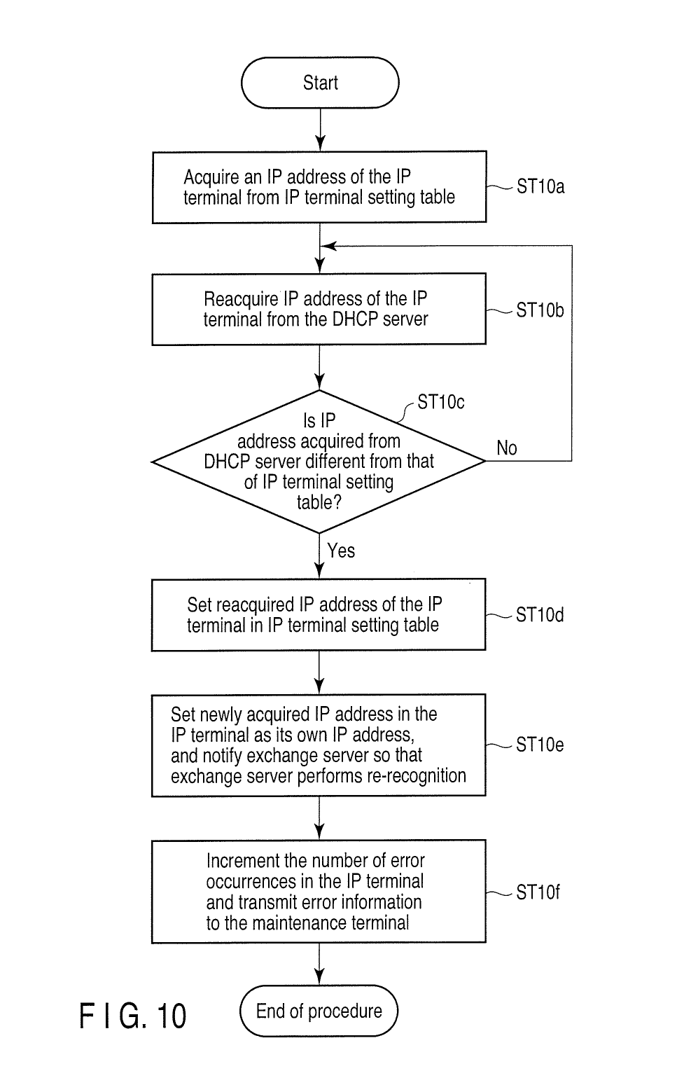

FIG. 10 is a flowchart illustrating the control processing procedure in which a recovery process “0” of the packet error distribution is executed in the exchange server BTB.

When the recovery process “0” is activated by the recovery control module 134, the exchange server BTB acquires an IP address of the IP telephone terminal T12 from the IP terminal setting table 142 in the storage module 14 (block ST10a).

After that, the exchange sever BTB reacquires the IP address of the IP telephone terminal T12 from the DHCP server SV (block ST10b), and judges whether the IP address reacquired from the DHCP server SV is different from the IP address acquired from the IP terminal setting table 142 (block ST10c).

When the reacquired IP address is different from the IP address of the IP telephone terminal T12 in the IP terminal setting table 142 (NO), the exchange server BTB shifts to block ST10b.

When the acquired IP address is different from the IP address of the IP telephone terminal T12 in the IP terminal setting table 142 (YES), the exchange server BTB sets the IP address of the reacquired IP telephone terminal T12 in the IP terminal setting table 142 (block ST10d), sets the newly acquired IP address as a IP address of itself in the IP telephone terminal T12, and informs the exchange server BTB to perform recognition (block ST10e).

Next, the exchange server BTB increments the number of times the error has occurred in the IP telephone terminal T12 in the IP terminal setting table 142 in the storage module 14, and transmits error information to the maintenance terminal MT (block ST10f). Thereby, the procedure ends.

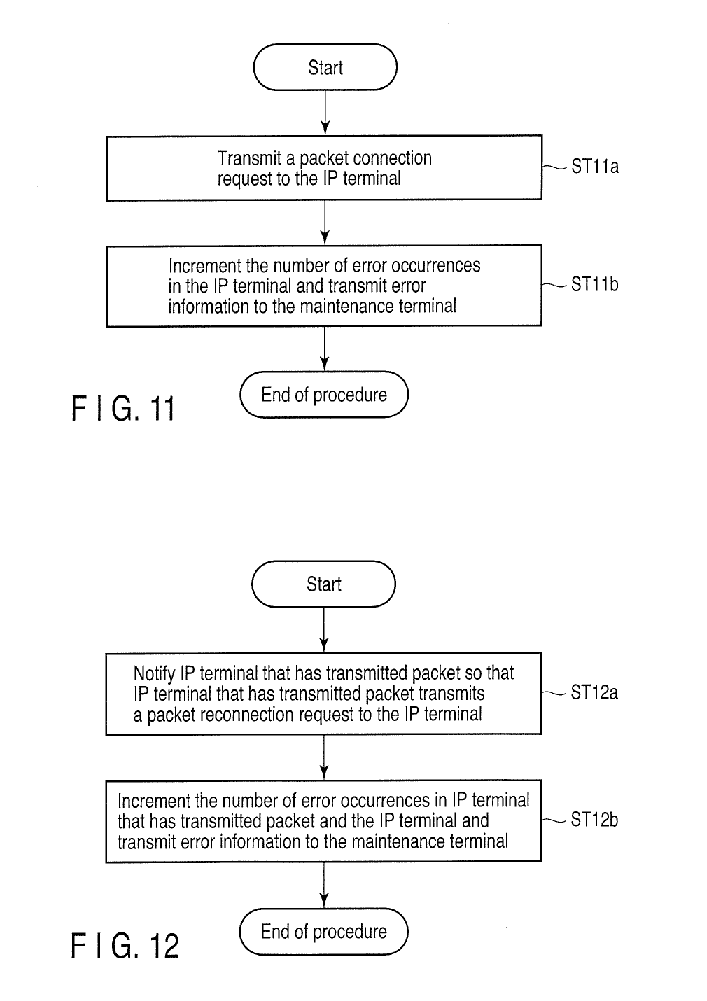

FIG. 11 is a flowchart illustrating the control processing procedure in which the recovery process “1” of the packet error distribution is executed in the exchange server BTB.

When the recovery process “1” is activated by the recovery control module 134, the exchange server BTB transmits a packet connection request to the IP telephone terminal T12 (block ST11a).

When the recovery control module 134 has activated a recovery process “1”, the exchange server BTB transmits a packet connection request to the IP telephone terminal T12 (block ST11a).

After that, the exchange server BTB increments the number of times errors have occurred in the IP telephone terminal T12 in the IP terminal setting table 142 in the storage module 14, transmits error information to the maintenance terminal MT (block ST11b), and thereby the procedure ends.

FIG. 12 is a flowchart illustrating the control processing procedure in which the recovery process “2” of the packet error distribution is executed in the exchange server BTB.

When the recovery process “2” is activated by the recovery control module, the exchange server BTB transmits a packet reconnection request to the IP telephone terminal T18 that has transmitted the packet to the IP telephone terminal T12 (block ST12a).

Next, the exchange server BTB increments the number of occurrence of errors in the IP telephone terminal T12 in the IP terminal setting table 142 in the storage module 14, transmits error information to the maintenance terminal MT (block ST12b), and thereby the procedure ends.

As described above, according to the second embodiment, when the exchange server BT that has received notification of packet error reception has judged that the IP telephone terminal T13 that has made the notification of packet error reception is receiving a call, transmits a connection request to the IP telephone terminal T13 that has made the notification, and transmits a reconnection request to the IP telephone terminal T18 that has transmitted the packet to the IP telephone terminal T12 that has made the notification when the IP telephone terminal T12 has been judged as carrying out communications, and acquires an IP address different from the IP address allocated to the IP telephone terminal T11 that has made the notification and changes setting of the IP address allocated to the IP telephone terminal T11 that has made the notification, to protect from the DoS attack when the IP telephone terminal T11 that has made the notification has been judged as being idle. Thereby, recovery can be performed without waiting for the recovery operation of the maintenance person.

As described above, according to the second embodiment, recovery can be made promptly without awaiting the recovery operation by the maintenance person, by causing the exchange server BT that has received a notification of packet error reception to transmit a connection request to the IP telephone terminal T13 that has made the notification when the IP telephone terminal T13 that has made the notification of the packet error reception has been judged as receiving a call, transmit a reconnection request to the IP telephone terminal T18 that has transmitted a packet to the IP telephone terminal T12 that has made the notification when the IP telephone terminal T12 has been judged as being engaged in a call, and acquire an IP address different from the IP address allocated to the IP telephone terminal T11 that has made the notification from the DHCP server SV in order to protect from a DoS attack, for example, and change setting of the IP address allocated to the IP telephone terminal T11 that has made the notification when the IP telephone terminal T11 that has made the notification has been judged as being idle.

In the above-described second embodiment, the processing load relating to the communication connection of the control module 12 may be monitored, and the recovery process may be activated only in the case when the processing load is equal to or smaller than a predetermined value. Thereby, the recovery process can be executed without affecting the other communication processes.

### Other Embodiments

The embodiment is not limited to the above-described embodiments. For example, the descriptions have been made with reference to the case where detection of packet error reception is started at timing when a talk has ended, but detection of packet error reception may be started in a waiting state as well. As timing when detection of error reception is started, the following may also be considered: “the detection start time is set in advance”; “detection is automatically started when the network to which the exchange system is connected has been judged as being abnormal before it is periodically diagnosed”; and “the time used by each of the IP telephone terminals is calculated on the exchange server side and a detection start request is transmitted to the IP telephone terminal that has reached a predetermined period of time”.

Further, in the above-described embodiments, a case has been described where the exchange server and the gateway are separately provided, but the gateway may be integrated in the exchange server.

Further, in the above-described embodiments, a case has been described where the exchange server and the DHCP server are separately provided, but the exchange server may be equipped with a DHCP function.

Other configurations, such as the configuration of the IP telephone system, the configuration of the function of the exchange server, the configuration of the function of the IP telephone terminal, the contents stored in the table, and the control procedure and its contents of the alarm notification control and the recovery processing control, may be varied as appropriate within the scope of the embodiment.

The various modules of the systems described herein can be implemented as software applications, hardware and/or software modules, or components on one or more computers, such as servers. While the various modules are illustrated separately, they may share some or all of the same underlying logic or code.

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

What is claimed is:

1. A method for coping with packet error distribution used in a communication system including a plurality of terminals connected to a communication network for packet communications and a server apparatus configured to execute communication connection between the plurality of terminals connected to the communication network, the method comprising:
causing each of the plurality of terminals to detect error reception of an unnecessary packet;
notifying the server apparatus of a message indicating that the error reception is detected when the error reception is detected;
causing the server apparatus to judge a communication connection state of a terminal that has made the notification when the message indicating that the error reception has been detected has been notified by the terminal; and
executing a process of preventing packet error distribution according to the judged communication connection state.

2. A server apparatus executing communication connection between a plurality of terminals connected to a communication network for packet communications, comprising:
a judgment module configured to judge a communication connection state of the terminal that made the notification, when a message indicating that error reception of an unnecessary packet is detected by the terminal; and
a controller configured to execute a process of preventing packet error distribution according to the communication connection state judged by the judgment module.

3. The server apparatus of claim 2, further comprising a memory configured to store a management table indicating a correspondence relation between a terminal ID and a connection ID and state information, when the communication connection between the plurality of terminals is established, wherein the connection ID is specifies a plurality of terminals between which communication connection is performed, wherein the state information indicates a communication connection state between the plurality of terminals,
the judgment module refers to the management table based on a terminal ID included in a message and judges a communication connection state of the terminal that made the notification based on a reference result of the management table, when the message indicating that error reception of an unnecessary packet has been detected is notified by the terminal.

4. The server apparatus of claim 2, wherein the controller notifies the terminal that has made the notification of the error reception or a maintenance terminal on the communication network of an alarm message according to the communication connection state judged by the judgment module.

5. The server apparatus of claim 2, wherein the controller executes a recovery process according to the communication connection state judged by the judgment module.

6. The server apparatus of claim 5, wherein the controller transmits a connection request to the terminal that has made the notification, when the terminal that has made the notification of the packet error reception has been judged as receiving a call by the judgment module.

7. The server apparatus of claim 5, wherein the controller transmits a reconnection request to a terminal that has transmitted the packet to the terminal that has made the notification, when the terminal that has made the notification of the packet error reception has been judged as being engaged in a call by the judgment module.

8. The server apparatus of claim 5, wherein the control module acquires a connection ID different from a connection ID allocated to the terminal that has made the notification, and allocates the different connection ID to the terminal that has made the notification, when the terminal that has made the notification of the packet error reception has been judged as being idle by the judgment module.

9. The server apparatus of claim 5, wherein the controller monitors a processing load relating to the communication connection and executes a recovery process according to the communication connection state only when the processing load is equal to or lower the predetermined value.

10. A terminal apparatus connected to a communication network for packet communications and communicated with and connected to a terminal on the communication network via a server apparatus of the communication network, comprising:
a detector configured to detect error reception of an unnecessary packet; and
a notification module configured to notify the server apparatus of a message when the error reception is detected by the detector, wherein the message indicates that the error reception is detected.

11. The terminal apparatus of claim 10, wherein the detector counts the number of packets abandoned in a preset period of time, and judges that packet error reception has occurred when the counted number is equal to or greater than a threshold value.

12. The terminal apparatus of claim 11, wherein the detector counts the number of packets abandoned in the period of time from the end of communication and judges that packet error reception has occurred when the counted number is equal to or greater than a threshold value.
